(19) United States
(12) Patent Application Publication
(10) Pub. No.: US 2026/0265905 A1
(43) Pub. Date: Sep. 10, 2026

(54) MATERIAL SELECTIVE DEPOSITION PROCESS

(71) Applicant: ASM IP Holding B.V., Almere (NL)

(72) Inventors: Marko Tuominen, Helsinski (FI); Vincent Vandalon, Heverlee (BE); David Zanders, Leuven (BE); YongGyu Han, Leuven (BE); Eva Elisabeth Tois, Espoo (FI); Aranzazu Maestre Caro, Leuven (BE)

(21) Appl. No.: 19/553,579

(22) Filed: Mar. 2, 2026

Related U.S. Application Data
(60) Provisional application No. 63/767,089, filed on Mar. 5, 2025.

(51) Int. Cl. C23C 16/04; C23C 16/40; C23C 16/455

(52) U.S. Cl. CPC C23C 16/042; C23C 16/403; C23C 16/45553

(57) ABSTRACT

Methods of and reactor systems for selectively depositing a material on a surface of a substrate are disclosed. Exemplary methods include using a first silanol to selectively form a blocking layer on a first region relative to a second region; selectively depositing a first material on the second region; and providing a second silanol to selectively remove the blocking layer from the first region or an activating compound to enhance growth of a second material on the first region.

### CROSS-REFERENCE TO RELATED APPLICATIONS

This application is a nonprovisional of, and claims priority to and the benefit of, U.S. Provisional Patent Application No. 63/767,089, filed Mar. 5, 2025 and entitled “MATERIAL SELECTIVE DEPOSITION PROCESS,” which is hereby incorporated by reference herein.

### FIELD OF INVENTION

The present disclosure relates generally to methods for selectively forming a material on a first region on a substrate relative to a second region on the substrate. More particularly, the disclosure relates to methods of selectively depositing material by selectively forming a passivation layer on a surface of the substrate.

### BACKGROUND OF THE DISCLOSURE

In some semiconductor device fabrication processes, it may be desirable to form a material only on certain areas of a substrate. Typically, such results are achieved by depositing a continuous film of the material and subsequently patterning the continuous film using lithography and etch steps. Such lithography and etch processes may be time consuming and expensive. Further, such processes may not provide the precision or resolution desired for many applications.

Recently, techniques have been developed to allow for selective deposition of material on a first region on a substrate relative to a second region on the substrate without using photolithography. Selective deposition processes may take a number of forms, including, but not limited to, selective dielectric deposition on dielectric surfaces (DoD), selective dielectric deposition on metallic surfaces (DOM), selective metal deposition on dielectric surfaces (MoD), and selective metal deposition on metallic surfaces (MoM).

Selective deposition on metallic surfaces (i.e., DoM, or MoM) may be of interest for providing simplified methods for selectively depositing a material over a metallic surface without the need for complex patterning and etch steps. Some techniques for selectively depositing material on a metal surface include use of a blocking layer and a plasma process to remove the blocking layer. While such techniques may work for some applications, use of the plasma process may cause unwanted damage to a surface of the substrate. Accordingly, improved methods are desired for selectively forming a material on a first region of a substrate relative to a second region of the substrate.

Any discussion of problems and solutions described in this section has been included in this disclosure solely for the purposes of providing a context for the present disclosure. Such should not be taken as an admission that any or all of the discussion is prior art or was known at the time the invention was made.

### SUMMARY OF THE DISCLOSURE

This summary is provided to introduce a selection of concepts in a simplified form. Exemplary concepts are described in further detail in the detailed description of example embodiments of the disclosure below. This summary is not intended to necessarily identify key features or essential features of the claimed subject matter, nor is it intended to be used to limit the scope of the claimed subject matter.

In accordance with various embodiments of the disclosure, a method is provided, the method including: providing a substrate within a reaction chamber of a reactor, the substrate including a first region and a second region; providing a first silanol to selectively form a blocking layer on the first region, relative to the second region; selectively depositing a first material on the second region; and providing a second silanol to modify the blocking layer.

In some embodiments, the first region includes a metal.

In some embodiments, the second region includes silicon or consists essentially of carbon.

In some embodiments, the first material includes a polymer.

In some embodiments, the method further includes selectively depositing a second material on the first region relative to the second region.

In some embodiments, the second silanol selectively removes the blocking layer from the first region and/or activates the blocking layer to enhance growth of the second material on the first region.

In some embodiments, the first silanol includes a compound represented by the formula SiₐRₓ(OH)_{y}(OR′)_{z}, where a is 1, 2, or 3, where x is 1, 2, or 3, where y is 1 or 2, where z=4-x-y for each silicon atom in the compound, where each R is independently selected from a linear or branched C1-C8 alkyl group, and where each R′ is independently selected from a linear or branched C1-C8 alkyl group.

In some embodiments, the first silanol includes one or more of bis(tert-pentoxy)methylsilanol, tert-butyl (tert-butoxy) silanediol, tert-pentyl(tert-pentoxy) silanediol, or tert-pentyl(tert-butoxy) silanediol.

In some embodiments, the second silanol includes a compound represented by the formula Si(OH)ₓ(OR)_{y}, where x is 1 or 2, where y is 2 or 3, and where each R is independently selected from a linear or branched C1-C6 alkyl group.

In some embodiments, the second silanol includes one or more of tris(tert-pentoxy) silanol or tris(tert-butoxy) silanol.

In some embodiments, the method further includes a treatment step before the step of providing the second silanol, the treatment step includes one or more of a direct plasma treatment, a remote plasma treatment, a UV treatment, or an e-beam treatment.

In some embodiments, the method further includes a treatment step after the step of providing the second silanol, the treatment step includes one or more of a direct plasma treatment, a remote plasma treatment, a UV treatment, or an e-beam treatment.

In some embodiments, the second material includes a metal, a semiconductor, a metal oxide, a semiconductor oxide, a metal nitride, a semiconductor nitride, a metal carbide or a semiconductor carbide.

In some embodiments, the second material is silicon oxide, aluminum oxide, yttrium oxide, titanium nitride, or silicon nitride.

In some embodiments, the second material is conductive or a high dielectric constant material.

In some embodiments, selectively depositing the second material includes a cyclical deposition process, one or more cycles of the cyclical deposition process include providing a metal precursor and providing a reactant including one or more of a reducing agent, an oxidizing agent, a carbonizing agent, or a nitriding agent.

In some embodiments, the metal precursor includes a metal and one or more ligands.

In accordance with various embodiments of the disclosure, a reactor system is provided, the reactor system including: a reaction chamber; a first silanol source, including a first vessel and a first silanol, coupled to the reaction chamber; a second silanol source, including a second vessel and a second silanol; at least one first material precursor source; and a controller configured to provide the first silanol to selectively form a blocking layer on a first region of a substrate, relative to a second region of the substrate, selectively deposit a first material on the second region, and provide the second silanol to selectively remove the blocking layer.

In accordance with various embodiments of the disclosure, a method is provided, the method including: providing a substrate within a reaction chamber of a reactor, the substrate including a first region and a second region; providing a first silanol to selectively form a blocking layer on the first region, relative to the second region; selectively depositing a first material on the second region; providing an activating compound to modify the blocking layer; and selectively depositing a second material on the first region relative to the second region; the activating compound enhances growth of the second material on the first region; and either the activating compound includes a group 13 element and the second material includes a group 14 element, or the activating compound includes a group 14 element and the second material includes a group 13 element.

In some embodiments, the group 14 element is silicon.

In some embodiments, the activating compound includes the group 14 element and is a second silanol.

In some embodiments, the group 13 element is aluminum.

In some embodiments, the second material is aluminum oxide.

For the purpose of summarizing the invention and the advantages achieved over the prior art, certain objects and advantages of the invention may have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIGS. 2-7 illustrate structures formed in accordance with examples of the disclosure.

FIG. 8 illustrates another method in accordance with examples of the disclosure.

FIGS. 9-12 illustrate structures formed in accordance with additional examples of the disclosure.

FIG. 13 illustrates a schematic diagram of a reactor system in accordance with examples of the disclosure.

FIG. 14 illustrates a schematic diagram of a reactor system having multiple reaction chambers, in accordance with examples of the disclosure.

FIG. 15 illustrates another structure in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure. The illustrations presented herein are not necessarily meant to be actual views of any particular material, structure, or system, but are merely representations that are used to describe embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As set forth in more detail below, various embodiments of the disclosure provide methods for selectively depositing material on one surface or region relative to another surface or region. Methods described herein can be used to form structures that can be used to, for example, form electronic devices, such as semiconductor devices, microelectromechanical devices, photonic devices, and the like.

As used herein, the term substrate can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include semiconductor material. Exemplary substrates include a first region of a first substrate material and a second region of a second substrate material, wherein the first substrate material and the second substrate material are different. The first region has a surface that may be called “first surface”, and a deposition “on the first region” is a deposition “on the first surface”. The second region has a surface that may be called “second surface”, and a deposition “on the second region” is a deposition “on the second surface”. As the process progresses, the nature of the material on the surface of the first region may evolve, for example if a material is deposited on the first region. Typically, the material of the first region is initially a first substrate material and may evolve to include a blocking layer and/or a second material. As the process progresses, the nature of the material on the surface of the second region may evolve, for example if a material is deposited on the second region. Typically, the material of the second region is initially a second substrate material and may evolve to include a first material.

As used herein, a structure can be or include a substrate as described herein. Structures can include a substrate and one or more layers overlying the substrate, such as one or more layers formed by a method according to the current disclosure.

As used herein, the term film and/or layer can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands.

As used herein, the term metallic surface may refer to surfaces including a metallic component, including, but not limited to, metal surfaces (e.g., elemental metal or a metal alloy), metal oxide surfaces, metal silicide surfaces, metal nitride surfaces, metal carbide surfaces, mixtures thereof, and the like. The term metallic surface may also include a surface of a native oxide of a metallic material.

As used herein, the term silicon surface or silicon-containing surface may refer to a surface that includes silicon and that may include additional elements. Exemplary silicon-containing materials include, for example, silicon, silicon oxides, silicon nitrides, silicon oxynitrides, silicon carbides, silicon oxycarbides, silicon carbon nitride, and mixtures thereof.

The term cyclic deposition process or cyclical deposition process can refer to the sequential introduction of precursors (and/or reactants) into a reaction chamber to deposit a layer over a substrate and includes processing techniques, such as atomic layer deposition (ALD), molecular layer deposition (MLD), cyclical chemical vapor deposition (cyclical CVD), and hybrid cyclical deposition processes that include an ALD component and a cyclical CVD component. In some cases, a cyclical deposition process can include continually flowing one or more precursors, reactants, or inert gases, and pulsing other of the precursors or reactants. The term MLD may refer to a vapor deposition process in which one or more deposition cycles are conducted in a process chamber. Typically, during each cycle an organic precursor is chemisorbed to a deposition surface (e.g., a substrate surface or a previously deposited underlying surface, such as material from a previous MLD cycle), typically forming a single molecular layer that does not readily react with additional organic precursor (i.e., a self-limiting reaction). Thereafter, if desired, another precursor (e.g., another organic precursor) may subsequently be introduced into the process chamber for use in forming the desired organic material on the deposition surface. Further, purging steps may also be utilized during each cycle to remove excess organic precursor from the process chamber and/or remove reaction byproducts from the process chamber after formation of the desired organic material.

As used herein, the term purge can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be effected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. For example, the term about can refer to +/−20, 10, 5, 2, or 1 percent of a value. The terms comprising, including, constituted by and having refer independently to typically or broadly comprising, comprising, consisting essentially of, or consisting of in some embodiments. In this disclosure, any defined meanings do not necessarily exclude ordinary and customary meanings, in some embodiments.

Although a number of example materials are given throughout the embodiments of the current disclosure, it should be noted that the chemical formulas given for each of the example materials should not be construed as limiting and that the non-limiting example materials given should not be limited by a given example stoichiometry.

As noted above, various examples of the disclosure relate to selectively forming material on one surface relative to another surface. Selectivity of forming or deposing material can refer to a relatively higher amount of material formed or deposited on a surface relative to another surface. For example, selectivity of deposition on surface A relative to surface B can be given as a percentage calculated by [(deposition on surface A)-(deposition on surface B)]/(deposition on the surface A). Deposition can be measured in any of a variety of ways. For example, deposition may be given as the measured thickness of the deposited material, or may be given as the measured amount (e.g., weight) of material deposited.

As set forth in more detail below, in embodiments described herein, selective deposition of a passivation film can be conducted on a first region (A) relative to a second region (B). Subsequently, a first material may be selectively deposited on the second region (B) relative to the passivation film (A). Yet further, a second material can be selectively deposited on the first region (A) relative to the first material/second region (B). In some embodiments, selectivity is greater than about 10%, or greater than about 50%, or greater than about 75%, or greater than about 85%, or greater than about 90%, or greater than about 93%, or greater than about 95%, or greater than about 98%, or greater than about 99%, or even greater than about 99.5%.

In some embodiments, deposition only occurs on one surface and does not occur on the other surface. It will be appreciated that a partially selective process can result in a fully selective structure by, for example, a post-deposition treatment.

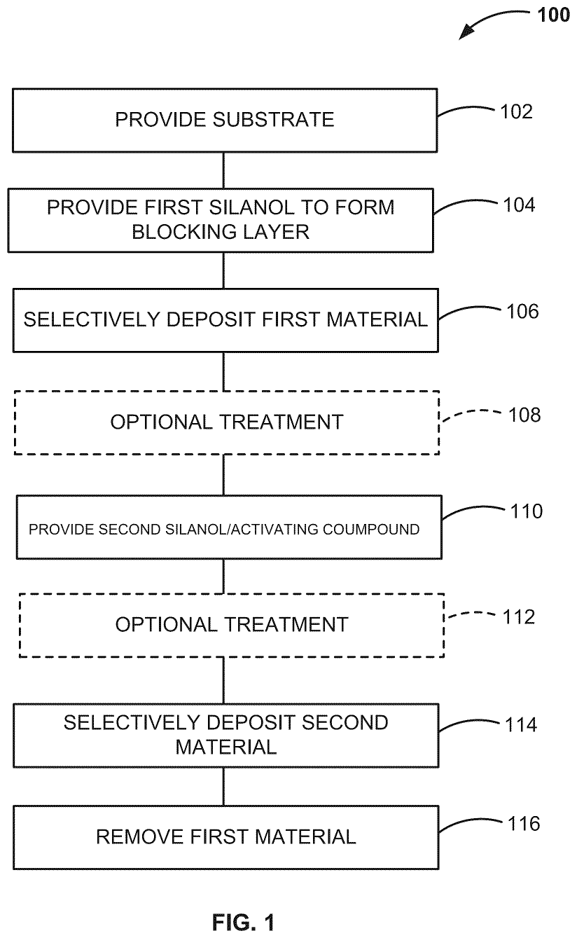

Turning now to the figures, FIG. 1 illustrates a method 100 of selectively depositing a material on a surface of a substrate in accordance with embodiments of the disclosure. Method 100 includes the steps of providing a substrate within a reaction chamber of a reactor (102), providing a first silanol to selectively form a blocking layer (104), selectively depositing a first material (106), optionally performing a treatment step (108), providing a second silanol and/or an activating compound (110), optionally performing a treatment after step 110 (112), selectively depositing a second material (114), and removing the first material (116).

During step 102, a substrate is provided within a reaction chamber. The reaction chamber can be a standalone reaction chamber or part of a cluster tool, such as a cluster tool described in more detail below. The reaction chamber can include a substrate heater to heat a substrate to a temperature noted herein. Additionally or alternatively, the reaction chamber can include rapid thermal processing apparatus, such as lamps, to heat the substrate.

The reaction chamber may be configured for performing all, or a portion, of the steps of method 100. In some embodiments of the disclosure, a first reaction chamber may be configured to perform one or more steps of method 100 and further reaction chamber(s) may be employed for other steps of method 100. However, in additional embodiments of the disclosure, the first reaction chamber may be configured to perform all of the steps of method 100.

Reactors and associated reaction chamber(s) capable of performing one or more steps of method 100 include atomic/molecular layer deposition (ALD/MLD) reaction chambers, plasma enhanced atomic layer deposition (PEALD) reaction chambers, as well as chemical vapor deposition (CVD) reaction chambers equipped with appropriate equipment and means for providing precursors. According to some embodiments, a showerhead reaction chamber may be used. According to some embodiments, a plasma reaction chamber, such as a PEALD reaction chamber, may be used. In such embodiments, the plasma may be direct, remote, or in near vicinity of the substrate. In some embodiments, the reactor is a spatial ALD reactor, in which the substrate moves or rotates during processing. In some cases, the reactor is a thermal reactor.

In some embodiments, a batch reactor may be used. In some embodiments, a vertical batch reactor is utilized in which the boat rotates during processing. For example, a vertical batch reactor may comprise a reaction chamber and an elevator constructed and arranged to move a boat configured for supporting a batch of between 10 to 200 substrates in or out of the reaction chamber.

In other embodiments, the batch reactor comprises a mini-batch reactor configured to accommodate 10 or fewer wafers, 8 or fewer wafers, 6 or fewer wafers, 4 or fewer wafers, or 2 wafers. In some embodiments in which a batch reactor is used, wafer-to-wafer non-uniformity is less than 3% (1sigma), less than 2%, less than 1% or even less than 0.5%.

Method 100 can optionally be carried out in a reactor and associated reaction chambers that form a cluster tool. In a cluster tool, each reaction chamber may be dedicated to one type of process, such that, for example, a temperature of the reaction chamber in each module can be kept constant, which can improve the throughput, compared to a reaction chamber in which the substrate is heated up to the process temperature before each run. Additionally, in a cluster tool, it is possible to reduce the time to pump the reaction space to the desired process pressure levels between substrates. In some embodiments of the disclosure, a stand-alone reactor can be equipped with a load-lock. In that case, it may not be necessary to cool down the reaction space between each run.

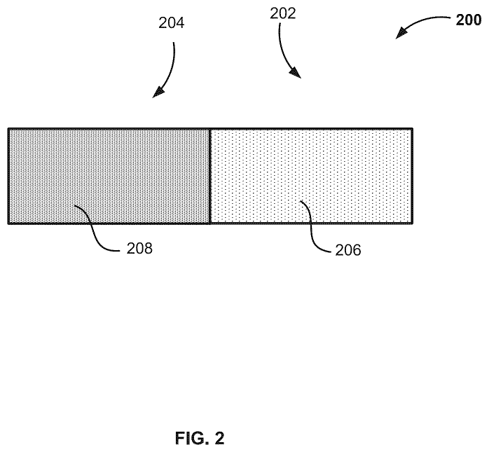

FIG. 2 illustrates a substrate 200 that can be supplied during step 102. Substate 200 provided during step 102 can include a first region 202 and a second region 204. First region 202 can include a first substrate material 206 and second region 204 can include a second substrate material 208 different than first substrate material 206. For example, first region 202 can be or include a metal. In some cases, first substrate material 206 is a metallic material. In some cases, first region 202 can be or include a (e.g., transition) metal oxide, (e.g., transition) metal nitride, (e.g., transition) metal carbide, or the like. In some cases, first region 202 can include a high dielectric constant material (e.g., dielectric constant higher than a dielectric constant of silicon oxide). Exemplary high dielectric constant materials include, for example, transition metal oxides, such as hafnium oxides, zirconium oxides, yttrium oxides, aluminum oxides, titanium oxides, and mixtures thereof. By way of particular examples, the first region can include one or more of W, Co, Cu, TiN, TaNₓ, TiOₓ, AlOₓ, HfOₓ, ZrOₓ, or YOₓ.

In some cases, the first region can include a plurality of metal-containing materials. For example, the first region can include a liner or barrier layer material and a fill material, such as a metal or metal alloy.

Second region 204 and/or second substrate material 208 can be or include silicon. By way of examples, second region 204 can be or include silicon, a silicon surface having native oxide (also a form of silicon oxide) formed thereover, SiCOₓ, SiOₓ, SiO₂, SiC, SiOC, SiCN, SiON, SiOCN, SiGe, SiN, or the like or a combination thereof. Alternatively, second region and/or second substrate material can consist of or consist essentially of carbon. For example, the second region may contain mainly carbon and other elements, such as hydrogen or the like. In such cases, second region may contain a carbon layer or an amorphous carbon layer.

Once the substrate has been loaded into a suitable reaction chamber, the substrate may be heated to a suitable temperature—e.g., for a degas or for subsequent step 104. By way of examples, the substrate can be heated to a temperature of about 150° C. to about 250° C. or about 250° C. to about 400° C. A pressure within the reaction chamber during step 102 can be between about 1 and about 5 or about 5 and about 10 torr.

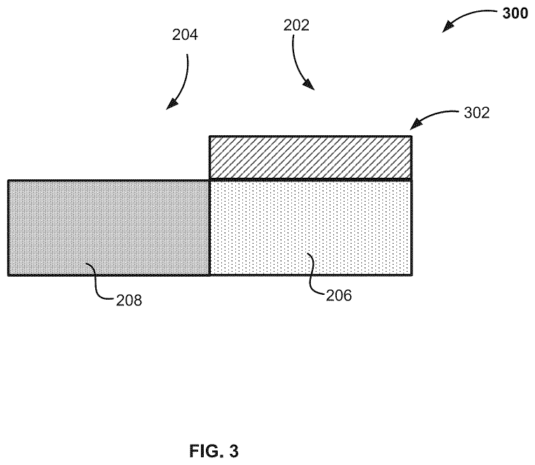

During step 104, a first silanol is provided to the reaction chamber to selectively form a blocking layer on the first region, relative to the second region. FIG. 3 illustrates a structure 300, including a blocking layer 302 selectively formed over first region 202, relative to second region 204.

The first silanol can be an organic silanol. By way of examples, the first silanol can be or include a compound represented by the formula:

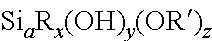

where a is 1, 2, or 3, where x is 1, 2, or 3, where y is 1 or 2, where z is an integer satisfying z=4-x-y for each silicon atom in the compound, where each R is independently selected from a linear or branched C1-C8 or C1-C6 alkyl group, and where each R′ is independently selected from a linear or branched C1-C8 or C1-C6 alkyl group. The alkyl and alkoxy ligands may or may not contain internal or terminal alkene or alkyne functional groups.

By way of particular examples, the first silanol can be or include one or more of bis(tert-pentoxy)methylsilanol, tert-butyl (tert-butoxy) silanediol, tert-pentyl(tert-pentoxy) silanediol, or tert-pentyl(tert-butoxy) silanediol.

A temperature within a reaction chamber during step 104 can be between about 200 and about 300° C. or between about 300 and about 400° C. A pressure within the reaction chamber can be between about 0 Torr and about 5 Torr or between about 5 Torr and about 20 Torr.

A thickness of the blocking layer (e.g., blocking layer 302) on the first region can be between about 0.1 nm and about 1 nm or between about 0.2 nm and about 1 nm. A selectivity of material deposited on the first region relative to the second region can be as described above.

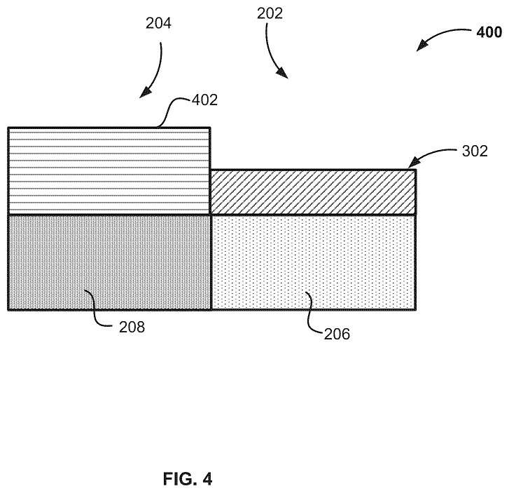

During step 106, a first material is selectively deposited on the second region, relative to the first region/the blocking layer. FIG. 4 illustrates a structure 400 including a first material 402 overlying second region 204. In this context, the first material deposited is distinct from the first substrate material of the substrate.

In accordance with examples of the disclosure, the first material is or includes a polymer. In accordance with additional examples, the first material is or includes organic material. In accordance with particular examples, the first material comprises one or more of a polyimide, polyamide, dimer, trimer, polyurethane, polythiourea, polyester, polyimine or a self-assembled monolayer material or other polymer capable of selectively forming on region 204.

Various precursors and reactants can be used to deposit the first material. Exemplary first material precursors and/or reactants include polyimide precursors, SAM precursors, small molecule inhibitor precursors, and area selective deposition precursors. In some cases, the first material is selectively deposited using a first material precursor and a first material reactant.

In some embodiments, the (e.g., organic) polymer is deposited by a cyclic process. For example, the deposition of the organic polymer may be an MLD process. In some embodiments, the cyclic deposition process for depositing the organic polymer comprises providing a first material reactant and a first material precursor alternately and sequentially into the reaction chamber.

In some embodiments, organic polymer precursors/reactants for use in the selective deposition of an organic polymer may be aliphatic compounds comprising 1-6 carbon atoms, 2-5 carbon atoms, 2-4 carbon atoms, 5 or fewer carbon atoms, 4 or fewer carbon atoms, 3 or fewer carbon atoms, or 2 carbon atoms. In some embodiments, the bonds between carbon atoms in the reactant or precursor may be single bonds, double bonds, triple bonds, or some combination thereof. In some embodiments, a first material reactant may comprise two amino groups.

In some embodiments, the amino groups of a first material reactant may occupy one or both terminal positions on an aliphatic carbon chain. However, in some embodiments, the amino groups of a first material reactant may not occupy either terminal position on an aliphatic carbon chain. In some embodiments, a first material reactant may comprise a diamine. In some embodiments, a first material reactant may comprise an organic polymer precursor selected from the group of 1,2-diaminoethane, 1,3-diaminopropane, 1,4-diaminobutane, 1,5-diaminopentane, 1,2-diaminopropane, 2,3-butanediamine, 2,2-dimethyl-1,3-propanediamine.

The first material reactant according to the current disclosure may comprise at least two carbon atoms, such as 1,2-diaminoethane. In some embodiments, first material reactant comprises three carbon atoms. In some embodiments, first material reactant comprises four carbon atoms. For example, first material reactant may be selected from 1,2-diaminobutane, 1,3-diaminobutane, 1,4-diaminobutane and 2,4-diaminobutane. Thus, in some embodiments, at least one of the amino groups is attached to a carbon atom that is bonded to two other carbon atoms. In other words, at least one of the amino groups may be located at the end of a carbon chain. In some embodiments, a diamine according to the current comprises five carbon atoms. In some embodiments, a diamine according to the current comprises six carbon atoms.

In some embodiments, the carbon chain of the first material reactant is branched. Thus, there is at least one carbon atom which is bonded to three or four other carbon atoms. In some embodiments, there is one such branching position in the first material reactant. In some embodiments, there are two such branching positions in the first material reactant. In some embodiments, there are three or more branching points. In some embodiments, the side chain from the longer carbon chain is a methyl group. In some embodiments, the side chain from the longer carbon chain is an ethyl group. In some embodiments, the side chain from the longer carbon chain is a propyl group. In some embodiments, the side chain from the longer carbon chain is an isopropyl group. In some embodiments, the side chain from the longer carbon chain is a butyl group. In some embodiments, the side chain from the longer carbon chain is a tert-butyl group. In some embodiments, the side chain of a first material reactant is a straight alkyl chain. In some embodiments, the side chain of a first material reactant is a branched alkyl chain. In some embodiments, the side chain of a first material reactant is a cyclic alkyl chain.

In some embodiments, the first material reactant is a C2 to C11 compound. The number of carbon atoms in the first material reactant typically influences the volatility of the compound such that a higher-weight compound may not be as volatile as a smaller compound. However, it was found out that intermediate-sized first material reactant containing, for example, four, five or six carbon atoms, may have suitable properties for being used as a first material reactant in the selective deposition processes according to the current disclosure. For example, 1,3-diaminopentane is liquid at room temperature, has a boiling point of 164° C. under atmospheric pressure, a vapor pressure of about 2.22 Torr at 25° C. and reaches a vapor pressure of 1 Torr at temperatures below 20° C. Thus, when 1,3-diaminopentane is used as a first material reactant for organic polymer deposition according to the current disclosure, the precursor vessel does not need to be heated. This may be advantageous for the on-tool lifetime of the precursor, as it may be less prone to degradation during continued use. Further, a liquid precursor has an advantage that precursor vessel loading is less expensive than for solid precursors. In some embodiments, the first material reactant comprises 1,3-diaminopentane.

In some embodiments of the disclosure, the amine groups of the first material reactant are attached to non-adjacent carbon atoms. This may have advantages for the availability for the amine groups to reactions with the first material precursor. In some embodiments, there is one carbon atom between the amino group-binding carbon atoms. In some embodiments, there is at least one carbon atom between the amino group-binding carbon atoms. In some embodiments, there are two carbon atoms between the amino group-binding carbon atoms. In some embodiments, there are at least two carbon atoms between the amino group-binding carbon atoms. In some embodiments, there are three carbon atoms between the amino group-binding carbon atoms. In some embodiments, there are at least three carbon atoms between the amino group-binding carbon atoms. In some embodiments, there are four carbon atoms between the amino group-binding carbon atoms. In some embodiments, there are at least four carbon atoms between the amino group-binding carbon atoms.

In some embodiments, the first material reactant comprises 1,5-diamino-2-methylpentane. Although the vapor pressure of 1,5-diamino-2-methylpentane is lower than that of 1,3-diaminopentane, it is also liquid at ambient temperature, and reaching vapor pressure of 1 Torr requires a moderate temperature of about 40° C.

In some embodiments, a carbon atom bonded with an amine nitrogen in the first material reactant is bonded to at least two carbon atoms. Thus, in some embodiments in which the first material reactant comprises five or more carbons, at least one of the amino groups may be located away from the end of a carbon chain. The structure of the first material reactant affects its properties in a vapor deposition process. Branching of a first material reactant, including the number of branches, and the relative position of the amino groups to the branches, may cause the deposited organic polymer to have different properties. Without limiting the current disclosure to any specific theory, for example, steric factors, may lead to certain reactions being preferred. This may offer the possibility to design a deposition process for a given purpose, taking into account, for example, the thermal budget, organic polymer growth speed requirements, necessary degree of selectivity, by using different first organic polymer precursors.

In some embodiments, the first material reactant is a cyclic diamine. In some embodiments, the first material reactant comprises one or more of a cyclopentanedialkylamine, cyclohexanedialkylamine, cyclopentadienedialkylamine, benzenedialkylamine, cyclopentanetrialkylamine, cyclohexanetrialkylamine, cyclopentadienetrialkylamine or benzenetrialkylamine.

In some embodiments, the first material reactant is an aromatic diamine. In some embodiments, the aromatic diamine is a diaminobenzene, such as 1,2-diaminobenzene, 1,3-diaminobenzene or 1,4-diaminobenzene. In some embodiments, the aromatic diamine comprises an alkylamino group in at least one position. For example, the alkylamino group may be a C1 to C3 alkylamino group, such as —CH₂NH₂, —(CH₂)₂NH₂, —(CH₂)₃NH₂, —CH(CH₃)NH₂ or —CH₂CH(CH₃)NH₂.

In some embodiments, the first material reactant is selected from a group consisting of 1,3-diaminopentane, 1,4-diaminopentane, 2,4-diaminopentane, 2,4-diamino-2,4-dimethylpentane, 1,5-diamino-2-methylpentane, 1,3-diaminobutane, 1,3-diamino-3-methylbutane, 2,5-diamino-2,5-dimethylhexane, 1,4-diamino-4-methylpentane, 1,3-diaminobutane, 1,5-diaminohexane, 1,3-diaminohexane, 2,5-diaminohexane, 1,3-diamino-5-methylhexane, 4,4,4-trifluoro-1,3-diamino-3-methylbutane, 2,4-diamino-2-methylpentane, 4-(1-methylethyl)-1,5-diaminohexane, 3-aminobutanamide, 1,3-diamino-2-ethylhexane, 2,7-diamino-2,7-dimethyloctane, 1,3-diaminobenzene and 1,4-diaminobenzene. In some embodiments, the first material reactant comprises a halogen.

In some embodiments, triamines may be used as a first material reactant in the deposition of organic polymer according to the current invention. Providing such molecules may advantageously affect the availability of polymerization sites for the second vapor-phase organic polymer precursor. The availability of three amine groups in a single molecule may lead to denser polymer network, which again may reduce the metal migration through the organic polymer. Such properties may be advantageous in embodiments utilizing the organic polymer according to the current disclosure as a passivation layer. Examples of suitable triamines include 1,2,3-triaminopropane, triamino butane (with amines in carbons 1, 2 and 3 or in carbons 1, 2 and 4), triamino pentane (especially with amines in carbons 1 and 5, plus in any one of the carbons 2, 3 or 4). Similarly, triamino hexanes may contain amine groups in carbons 1 and 6, as well as in any one of the positions 2, 3, 4 or 5; triamino heptanes may contain amine groups in carbons 1 and 7, as well as in any one of the positions 2, 3, 4, 5 or 6; and triamino octanes may contain amine groups in carbons 1 and 8, as well as in any one of the positions 2, 3, 4, 5, 6 or 7. Further, branched carbon chains, notably 2-aminomethyl-1,3-diaminopropane, 2-aminomethyl-1,4-diaminobutane (or alternatives having the two amino groups elsewhere in the butane chain), 2-aminomethyl-1,5-diaminopentane (or alternatives having the two amino groups elsewhere in the pentane chain), 3-aminomethyl-1,5-diaminopentane (or alternatives having the two amino groups elsewhere in the pentane chain), 2-aminomethyl-1,6-diaminohexane (or alternatives having the two amino groups elsewhere in the hexane chain), 3-aminomethyl-1,6-diaminohexane (or alternatives having the two amino groups elsewhere in the hexane chain), 3-aminoethyl-1,6-diaminohexane (or alternatives having the two amino groups elsewhere in the hexane chain). Also, an aromatic triamine, such as 1,3,5-triaminobenzene, may be an alternative for certain embodiments.

In some embodiments, the first material reactant for use in the selective cyclical deposition processes described herein may have the general formula:

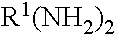

wherein R¹ may be an aliphatic carbon chain comprising 1-5 carbon atoms, 2-5 carbon atoms, 2-4 carbon atoms, 5 or fewer carbon atoms, 4 or fewer carbon atoms, 3 or fewer carbon atoms, or 2 carbon atoms.

By way of particular examples, the first material reactant may be selected from the group consisting of 1,2-diaminoethane (I), 1,3-diaminopropane (I), 1,4-diaminobutane (I), 1,5-diaminopentane (I), 1,2-diaminopropane (I), 2,3-butanediamine, 2,2-dimethyl-1,3-propanediamine (I), 1,6-diaminohexane, 1,4-diaminocyclohexane, or any other monomer with two reactive groups, tris(2-aminoethyl)amine, or a cyclic compound comprising at least two primary amine groups, such as 1,4-diaminocyclohexane (noted above) or p-phenylenediamine.

In some embodiments, the first material precursor is an organic reactant capable of reacting with adsorbed species of the first material reactant under the deposition conditions. In some cases, the terms reactant and precursor can be used interchangeably.

In some embodiments, the first material precursor is an anhydride, such as furan-2,5-dione (maleic acid anhydride). The anhydride can be a dianhydride, e.g., pyromellitic dianhydride. In some embodiments, the first material precursor can be any other monomer with two reactive groups which will react with the first reactant.

In some embodiments, the first material precursor and/or reactant does not contain metal atoms. In some embodiments, the first material precursor and/or reactant does not contain semimetal atoms. In some embodiments, one of the first material precursor and/or reactant comprises metal or semimetal atoms. In some embodiments, the first material precursor and/or reactant contain carbon and hydrogen and one or more of the following elements: N, O, S, P or a halide, such as Cl or F.

In some embodiments, a first material precursor comprises an organic compound selected from the group of 1,4-diisocyanatobutane, or 1,4-diisocyanatobenzene. In some embodiments, a first material precursor comprises an organic precursor selected from the group of: terephthaloyl dichloride, alkyldioyl dichlorides, such as hexanedioyl dichloride, octanedioyl dichloride, nonanedioyl dichloride, decanedioyl dichloride, or terephthaloyl dichloride. In some embodiments, a first material precursor comprises an organic precursor selected from the group of 1,4-diisothiocyanatobenzene, or terephthalaldehyde. In some embodiments, a first material precursor being vaporized can also be a diamine, such as, for example, 1,4-diaminobenzene, decane-1,10-diamine, 4-nitrobenzene-1,3-diamine, 4,4′-oxydianiline, or ethylene diamine. In some embodiments, a first material precursor can be a terephthalic acid bis(2-hydroxyethyl) ester. In some embodiments, a first material precursor can be a carboxylic acid, for example, alkyl-, alkenyl-, alkadienyl-dicarboxylic or tricarboxylic acid, such as ethanedioic acid, propanedioic acid, butanedioic acid, pentanedioic acid or propane-1,2,3-tricarboxylic acid. In some embodiments, a first material precursor can be an aromatic carboxylic or dicarboxylic acid, such as benzoic acid, benzene-1,2-dicarboxylic acid, benzene-1,4-dicarboxylic acid or benzene-1,3-dicarboxylic acid. In some embodiments, a first material precursor may comprise one or more OH-groups bonded to a hydrocarbon. In some embodiments, a first material precursor can be selected from the group of diols, triols, aminophenols, such as 4-aminophenol, benzene-1,4-diol or benzene-1,3,5-triol. In some embodiments, a first material precursor can be 8-quinolinol. In some embodiments, the first material precursor can comprise alkenylchlorosilanes, like alkenyltrichlorosilanes, such as 7-octenyltrichlorosilane.

Exemplary SAM precursors include octadecyl-tris(dimethylamino) silane, octyl-tris(dimethylamino) silane, octadecyltrichlorosilane, octyl-trichlorosilane, octyl-trimethoxysilane, other tri-halo silanes with alkyl chains of C1 to C20, and other tri-alkoxy silanes with alkyl chains of C1 to C20.

Exemplary small molecule inhibitor precursors include a silylating agent. A silylating agent according to the current disclosure can be provided in a vapor phase. In some embodiments, a silylating agent comprises one or more of allyltrimethylsilane, bis(dimethylamino)dimethylsilane, bis(dimethylamino) diethylsilane, halosilane, for example, chlorotrimethylsilane or octadecyltrichlorosilane, an imidazole, for example, N-(trimethylsilyl) imidazole, a silazane, for example, hexamethyldisilazane, a silylamine, for example, N-(trimethylsilyl)dimethylamine or 1,1,1-trimethoxy-N,N-dimethylsilanamine or a pyrrole, such as 1-(triisopropylsilyl) pyrrole. The substrate may be contacted with a sufficient quantity of the blocking agent and for a sufficient period of time that the top surface is selectively blocked with silicon species. In some embodiments, the second substrate material is not passivated with a self-assembled monolayer.

Exemplary area selective deposition precursors can include one or more metal precursors, such group 13 (e.g., Al, Ga, and/or In) precursors, transition metal (e.g., Ti, Zr, and/or Hf, excluding technetium) precursors, rare earth metal (e.g., Y, La, and/or Sc) precursors, and/or group 14 metal or metalloid (e.g., Si) precursors. One or more suitable reactants can be used to form, for an oxide, nitride and/or carbide comprising one or more such metals. For example, the selective deposition precursors and a reactant can be used to deposit one or more of AIO, SiO, TiO, ZrO, HfO YO, LaO, ScO, TIN, SiN, AlN, ZrN, HfN, LaN, ScN or the like.

Exemplary metal precursors suitable for area selective deposition include a heteroleptic precursor comprising a metal, at least one cyclopentadienyl ligand, and at least one amidinato ligand. In this context, Si can be considered a metal. In some embodiments, the cyclopentadienyl ligand comprises at least one C1 to C5 alkyl substituent. In some embodiments, the alkyl substituent is selected from a group consisting of methyl, ethyl and linear or branched alkyl groups containing three, four or five carbon atoms. In some embodiments, the metal precursor comprises two ethylcyclopentadienyl ligands. In some embodiments, the amidinato ligand comprises an acetamidinato ligand. In some embodiments, the acetamidinato ligand is an alkylacetamidinato ligand. In some embodiments, the alkylacetamidinato ligand is a dialkylacetamidinato ligand. In some embodiments, the one or two alkyl groups of the alkylacetamidinato ligand are selected from a group consisting of methyl, ethyl, n-propyl, isopropyl, n-butyl, tert-butyl and sec-butyl. A reactant or oxygen precursor can be selected from a group consisting of molecular oxygen, ozone, hydrogen peroxide, and water or a nitriding agent or carbonizing agent, such as described herein.

A temperature within a reaction chamber during step 106 can be between about 100° C. and about 200° C. or between about 200° C. and about 400° C. A pressure within the reaction chamber can be between about 0 Torr and about 5 Torr or between about 5 Torr and about 20 Torr.

A thickness of the first material layer (e.g., first material 402) on the second region 204 can be between about 0.1 nm and about 2.5 nm or between about 2.5 nm and about 7.5 nm. A selectivity of the first material deposited on the second region relative to the first region can be as described above.

During step 108, an optional treatment of the deposited first material is performed—e.g., before step 110. In some cases, step 108 includes one or more of a direct plasma treatment, a remote plasma treatment, a UV treatment, an e-beam treatment, or use of other energetic beams. In some cases, step 108 includes providing one or more gases to a reaction chamber. The one or more gases can be used to form excited species using one or more of the excitation techniques noted herein. Such gases can include one or more of Ar, N₂, He, Ne, O₂, H₂ and any mixtures thereof.

During step 110, a second silanol and/or an activating compound is provided. As described in more detail below, the second silanol can selectively remove the blocking layer from the first region and/or enhance or boost growth of a second material on the first (or activated first) region. The activating compound, which may be the second silanol, enhances or boosts growth of a second material on the first (or activated first) region, which may, or not, or only partially, still comprise the blocking layer.

The second silanol can be an organic silanol. By way of examples, the second silanol can be or include a compound represented by the formula:

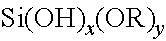

where x is 1 or 2, where y is 2 or 3, and where each R is independently selected from a linear or branched C1-C8 or C1-C6 alkyl group. By way of particular example, the second silanol can include one or more of tris(tert-pentoxy) silanol or tris(tert-butoxy) silanol.

In embodiments, the activating compound provided comprises a group 13 element and is configured to enhance growth of a material containing a group 14 element during step 114. The activating compound may include an aluminum-containing species capable of forming surface aluminoxy or aluminate terminations on the first region 202. Examples include vapor-phase aluminum alkoxides or low-dose pulses of an aluminum organometallic precursor. For example, in the case of the group 14 element being silicon, the presence of aluminum-derived surface sites modifies the blocking layer and increases the reactivity of the first region toward silicon precursors used in forming silicon-containing second materials like silicon oxide.

In embodiments, the activating compound provided comprises a group 14 element and is configured to enhance growth of a material containing a group 13 in step 114. In particular, a silicon-containing activating compound, such as a second silanol, may be dosed to form surface siloxy and/or silanol terminations on the first region 202 without substantially depositing a bulk silicon-containing film. Suitable activating species include vapor-phase silanols and alkoxysilanes, for example tris(tert-butoxy) silanol or tris(tert-pentoxy) silanol. The presence of silicon-derived —Si—O(H) surface sites modifies the blocking layer and increases the reactivity of the first region toward aluminum precursors used in forming aluminum-containing second materials, such as aluminum oxide, thereby increasing nucleation density and initial growth per cycle while maintaining selectivity.

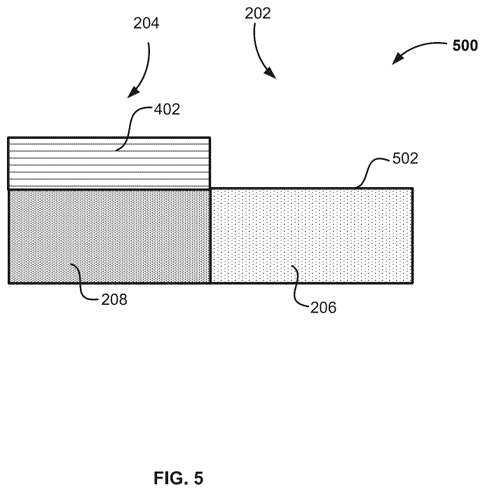

FIG. 5 illustrates a structure 500 that includes a surface 502 on which blocking layer 302 has been removed and/or that has been activated (e.g., for subsequent material deposition) using the second silanol.

A temperature within a reaction chamber during step 110 can be between about 100° C. and about 200° C. or between about 200° C. and about 400° C. A pressure within the reaction chamber can be between about 0 Torr and about 5 Torr or between about 5 Torr and about 20 Torr. In some cases, steps 104 and 110 can be performed in the same reaction chamber. In some cases, deposition of other materials and/or treatment steps can be performed in the same or different reaction chambers.

As illustrated in FIG. 1, method 100 can include a treatment step 112 after step 110. Treatment step 112 can be or include any of the treatment steps noted above in connection with step 108. If method 100 includes both steps 108 and 112, the respective treatment steps can be the same or different—e.g., different in time, type, power used to form excited species, or the like.

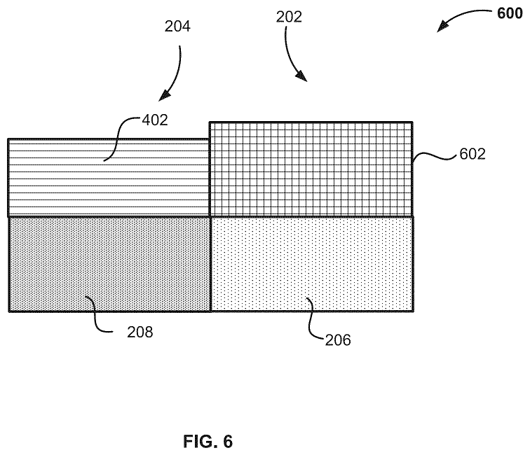

During step 114, a second material is selectively deposited over first region 202. FIG. 6 illustrates a structure 600, which includes second material 602 formed overlying first substrate material 206. In accordance with examples, the second material comprises a metal or a semiconductor. In accordance with further examples, the second material is conductive or a high dielectric constant material. In some cases, the second material is or includes a metal oxide, a semiconductor oxide, a metal nitride, or a metal carbide. In some cases, the second material is or includes silicon oxide, aluminum oxide, yttrium oxide, titanium nitride, or silicon nitride. The second material may be doped and/or oxidized. For example, the second material may be carbon-doped silicon nitride or oxidized carbon-doped silicon nitride.

Step 114 of selectively depositing a second material on the first region relative to the second region can include a cyclical deposition process. Step 114 can include providing a metal precursor and providing a reactant comprising one or more of a reducing agent, an oxidizing agent, a carbonizing agent, or a nitriding agent. Such steps can be separated by a purge step.

Exemplary metal precursors suitable for use in step 114 include a metal and one or more ligands. By way of examples, the ligands can include one or more of alkyls, alkoxides, diketonates, acetamidinates, formamidinates, guanidinates, amides, alkoxyamines, aryls, cyclopentadienyls, halogens.

Exemplary reducing agents suitable for use during step 114 include H₂ or the like. Exemplary oxidizing agents suitable for use during step 114 include O₂, H₂O, H₂O₂, O radicals, O ions, alcohols, such as ethanol, isopropanol, tert-butanol, or the like. Exemplary carbonizing agents suitable for use during step 114 include methane, ethane, or the like. Exemplary nitriding agents suitable for use during step 114 include N₂, NH₃, NH₂—NH₂, alkyl hydrazines.

When step 110 includes an activating compound comprising a group 14 element that is silicon (e.g. the activating compound is the second silanol), the second material selectively deposited on the first region may for example comprise aluminum oxide. In some embodiments, the cyclical deposition process includes alternating pulses of an aluminum precursor, such as trimethylaluminum, and an oxidizing agent, such as water, hydrogen peroxide, ozone, or oxygen plasma, with intervening purges. Without wishing to be bound by theory, it is believed that the activation achieved by the second silanol increases growth-per-cycle, reduces incubation delay, and improves selectivity of Al₂O₃ on the first region relative to the second region, while maintaining the blocking performance over the first material on the second region.

When step 110 includes an activating compound comprising a group 13 element that is aluminum, the second material selectively deposited on the first region may, for example, comprise silicon oxide. In some embodiments, the cyclical deposition process includes alternating pulses of a silicon precursor, such as a silanol or an alkoxysilane (e.g., tris(tert-butoxy) silanol, tris(tert-pentoxy) silanol, or tetraethyl orthosilicate), and an oxidizing agent, such as water, hydrogen peroxide, ozone, or oxygen plasma, with intervening purges. Without wishing to be bound by theory, it is believed that the activation achieved by the aluminum-containing species increases growth-per-cycle, reduces incubation delay, and improves selectivity of SiO₂ on the first region relative to the second region, while maintaining the blocking performance over the first material on the second region.

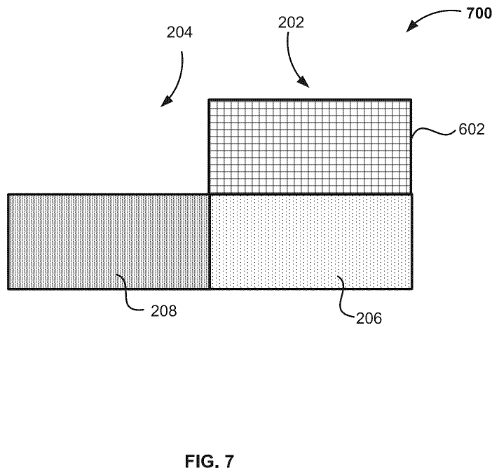

During step 116, the first material is selectively removed. FIG. 7 illustrates a structure 700, in which the first material 402 is selectively removed from the second region 204. Step 116 can include any suitable process, such as a direct, indirect, or remote plasma process, which produces excited hydrogen species. By way of particular examples, step 116 can include a hydrogen (e.g., H₂) plasma process.

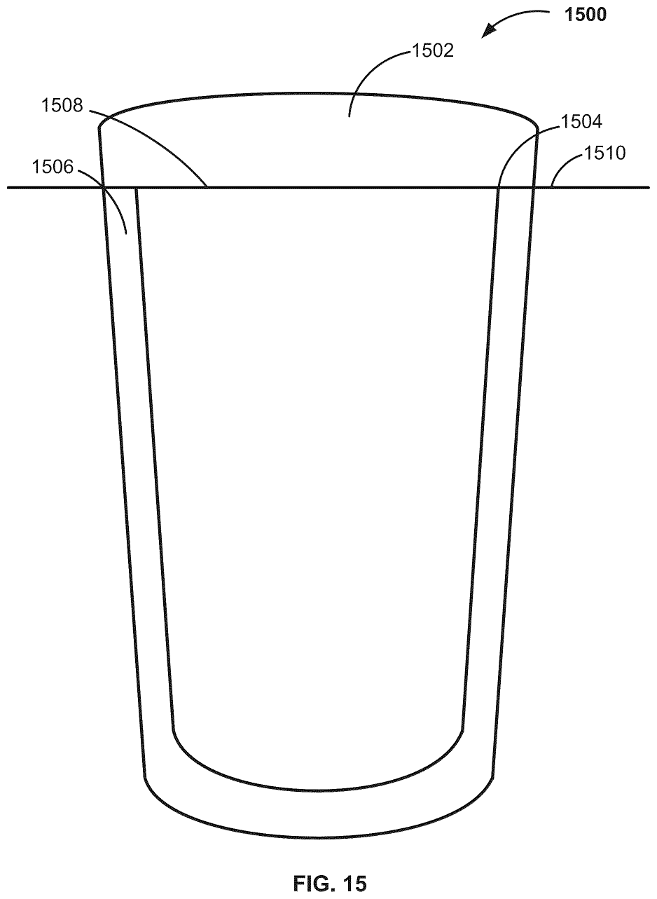

FIG. 15 illustrates a structure 1500 that includes a second material 1502 selectively formed overlying a first region 1504 that includes a barrier or liner layer 1506 (e.g., a metal nitride or the like, such as TiN, TaN, MON, Ru) and a bulk metallic surface 1508 as described herein. A surface 1510 can be a silicon-containing surface as described above.

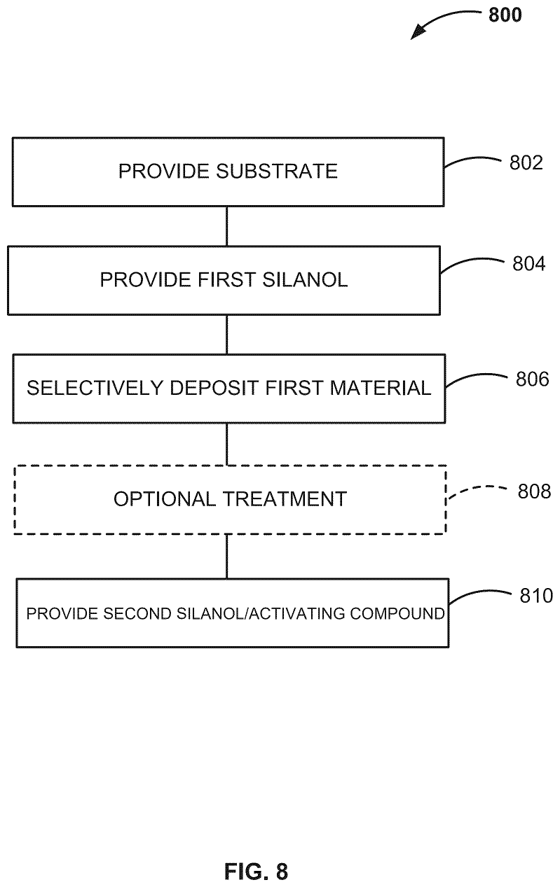

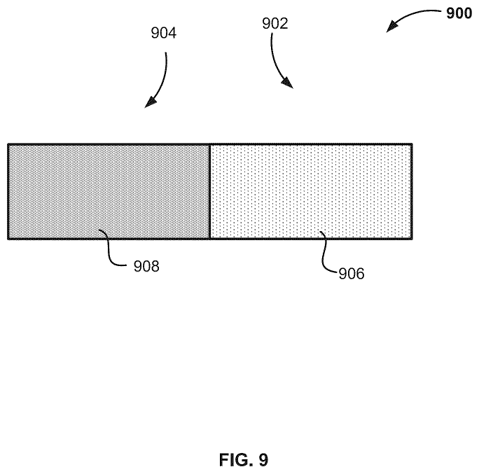

FIG. 8 illustrates another method 800 of selectively depositing a material on a surface of a substrate. Method 800 includes the steps of providing a substrate within a reaction chamber of a reactor (802), providing a first silanol to selectively form a blocking layer (804), selectively depositing a first material (806), optionally performing a treatment step (808), and providing a second silanol and/or an activating compound (810). FIGS. 9-12 illustrate structures that can be formed using method 800.

Steps 802, 804, 808, and 810 can be the same or similar to steps 102, 104, 108, and 110 described above. Method 800 differs from method 100 in that method 800 need not include deposition of a second material and may include deposition of different types of materials during step 806, compared to materials deposed during step 106.

FIG. 9 illustrates a substrate that can be provided during step 802. Substrate 900 can be the same or similar to substrate 200, described above. Similar to substrate 200, substrate 900 includes a first region 902, a second region 904, a first substrate material 906, and a second substrate material 908, which can be the same or similar to first region 202, second region 204, first substrate material 206, and a second substrate material 208 described above.

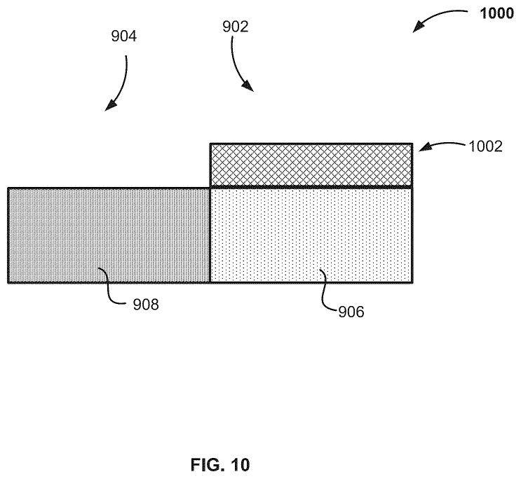

FIG. 10 illustrates structure 1000 formed during step 804. Structure 1000 can be the same or similar to structure 300 described above. Structure 1000 includes a blocking layer 1002 selectively formed over first region 902, relative to second region 904.

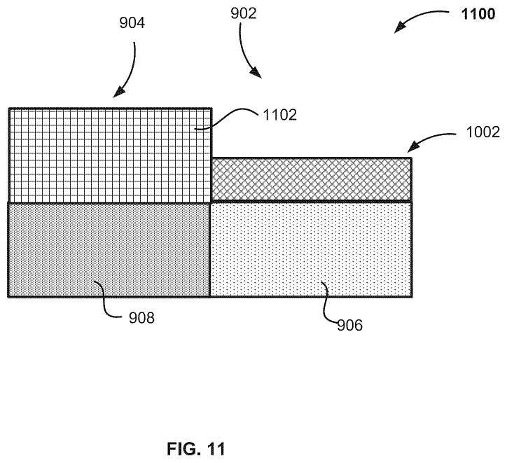

Similar to step 106, during step 806, a first material is selectively deposited on the second region. FIG. 11 illustrates a structure 1100 formed during step 806. As illustrated, structure 1100 includes first material 1102 selectively formed over second region 904.

First material 1102 can be or include a metal oxide, a metal nitride, a metal carbide, a metalloid oxide, a metalloid nitride, or a metalloid carbide. By way of examples, a metal oxide, nitride, or carbide can include one or more metals, such as one or more group 13, transition metal, and/or rare earth metal. The metalloid oxide, nitride, or carbide can include one or more of Si, Ge or the like.

In accordance with examples of the disclosure, step 806 includes providing a metal (or metalloid) precursor and providing a reactant comprising one or more of a reducing agent, an oxidizing agent, a carbonizing agent, or a nitriding agent. Step 806 can be or include a cyclical deposition process.

In accordance with examples of the disclosure, the metal or metalloid precursor can include a metal and one or more ligands. Exemplary ligands can include alkyls, alkoxides, diketonates, acetamidinates, formamidinates, guanidinates, amides, alkoxyamines, aryls, cyclopentadienyls, halogens. By way of examples, the metal precursor can include one or more metal precursors, such as group 13 (e.g., Al, Ga, and/or In) precursors, transition metal (e.g., Ti, Zr, and/or Hf, excluding technetium) precursors, rare earth metal (e.g., Y, La, and/or Sc) precursors, and/or group 14 metal or metalloid (e.g., Si) precursors. Exemplary reducing agents, oxidizing agents, carbonizing agents, or nitriding agents include those provided above in connection with step 114.

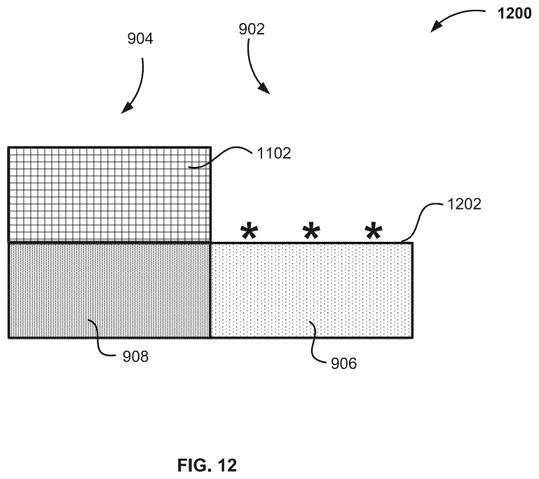

During step 810, a second silanol and/or an activating compound is provided. The second silanol can selectively remove the blocking layer from the first region and/or enhance or boost growth of a second material on the first (or activated first) surface. The activating compound, which may be the second silanol, enhances or boosts growth of a second material on the first (or activated first) surface, which may, or not, or only partially, still comprise the blocking layer. FIG. 12 illustrates a structure 1200 after step 810. Structure 1200 includes an activated surface 1202.

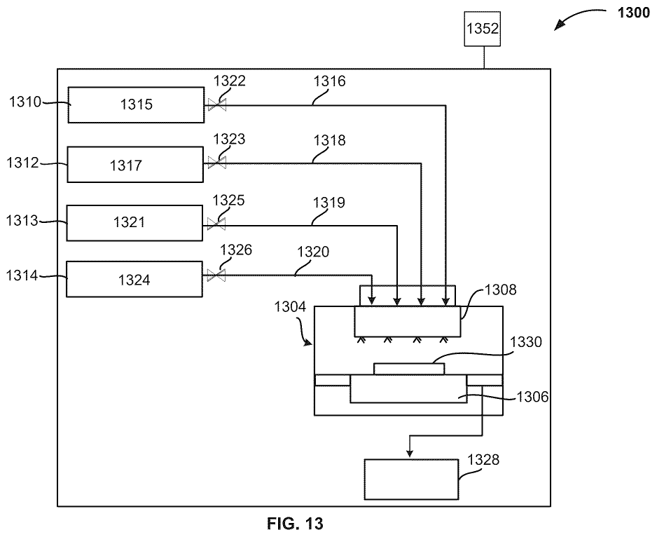

Referring now to FIG. 13, in various examples, a reactor system 1300 includes a reaction chamber 1304, a susceptor 1306 to hold a substrate 1330 during processing, a gas distribution system 1308 (e.g., a showerhead) to distribute one or more precursors and/or reactants to a surface of substrate 1330, one or more precursor or reactant sources 1310, 1312, and/or 1313, and/or a carrier and/or purge gas source 1314, fluidly coupled to reaction chamber 1304 via respective lines 1316, 1318, 1319 and 1320, and respective valves or controllers 1322, 1323, 1325 and 1326. Substrate 1330 can include a substrate or structure as described herein. A purge/carrier gas 1324 from gas source 1314 can be flowed to and through reaction chamber 1304 to act as a carrier gas, and/or purge or remove any excess reactant or other undesired materials from reaction chamber 1304. Sources 1310, 1312, and 1313 can include vessels and a precursor or reactant as described herein. For example, source 1310 can include a vessel and a first silanol 1315; source 1312 can include a vessel and a second silanol 1317; source 1313 can include a vessel and a first material precursor 1321. Reactor system 1300 can include additional sources. System 1300 can also include a vacuum source 1328 fluidly coupled to the reaction chamber 1304. Vacuum source 1328 can be configured to evacuate reactants, a purge gas, or other materials out of reaction chamber 1304.

Reactor system 1300 also includes a controller 1352. Controller 1352 can be configured to perform various functions and/or steps as described herein. Controller 1352 can include one or more microprocessors, memory elements, and/or switching elements to perform the various functions. Although illustrated as a single unit, controller 1352 can alternatively comprise multiple devices. Controller 1352 can be used to control gas flow (e.g., by monitoring flow rates and controlling valves 1322, 1323, 1325 and/or 1326), motors, heaters, cooling devices and/or vacuum source 1328 to execute various processes (e.g., method 100 or 800). Further, when a system includes two or more reaction chambers, as described in more detail below, the two or more reaction chambers can be coupled to the same/shared controller. By way of example, controller 1352 can be configured to provide a first silanol to selectively form a blocking layer on a first region of a substrate, relative to a second region of the substrate, selectively deposit a first material on the second region, and provide a second silanol to selectively remove the blocking layer and/or activate the first region.

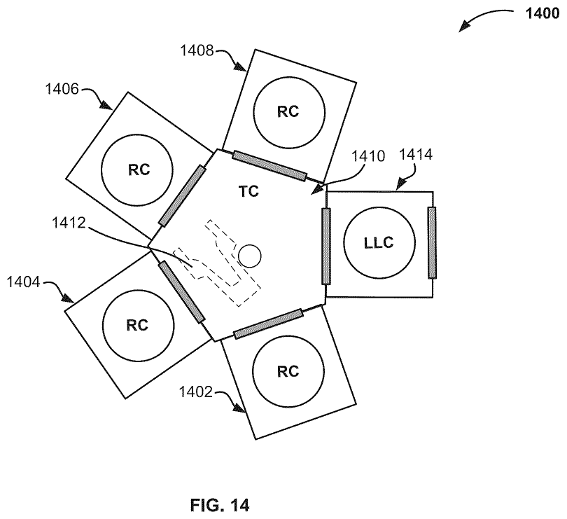

FIG. 14 illustrates a reactor system 1440 that includes a plurality of reaction chambers 1402-1408, each of which can be an example of reaction chamber 1304 in FIG. 13. Reaction chambers 1402-1408 can be disposed around and/or coupled to a transfer chamber 1410 that includes a transfer tool 1412 for transferring substrates between reaction chambers 1402-1408 and a load lock chamber 1414 and between reaction chambers 1402-1408 (e.g., through transfer chamber 1410). For example, a substrate 1330 can be disposed in different chambers for different steps of a method described herein. For example, one of reaction chambers 1402-1408 can be used to form or provide a first silanol and/or second silanol as described herein, another one of reaction chambers 1402-1408 can be used to selectively deposit a first material, another one of reaction chambers 1402-1408 can be used to selectively deposit a second material, and another one of reaction chambers 1402-1408 can be used to form a treatment as described herein. Other configurations are also possible, such that one or more steps of method 100 or 800 are performed within a single reaction chamber.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of selectively depositing a material on a surface of a substrate, the method comprising the steps of:
providing a substrate within a reaction chamber of a reactor, the substrate comprising a first region and a second region;
providing a first silanol to selectively form a blocking layer on the first region, relative to the second region;
selectively depositing a first material on the second region; and
providing a second silanol to modify the blocking layer.

2. The method of claim 1, wherein the first region comprises a metal.

3. The method of claim 1, wherein the second region comprises silicon or consists essentially of carbon.

4. The method of claim 1, wherein the first material comprises a polymer.

5. The method of claim 1, further comprising selectively depositing a second material on the first region relative to the second region.

6. The method of claim 5, wherein the second silanol selectively removes the blocking layer from the first region and/or is an activating compound activating the blocking layer to enhance growth of the second material on the first region.

7. The method of claim 5, wherein the second material comprises a metal, a semiconductor, a metal oxide, a semiconductor oxide, a metal nitride, a semiconductor nitride, a metal carbide or a semiconductor carbide.

8. The method of claim 7, wherein the second material is silicon oxide, aluminum oxide, yttrium oxide, titanium nitride, or silicon nitride.

9. The method of claim 5, wherein the second material is conductive or a high dielectric constant material.

10. The method of claim 5, wherein selectively depositing the second material comprises a cyclical deposition process, wherein one or more cycles of the cyclical deposition process comprise:
providing a metal precursor; and
providing a reactant comprising one or more of a reducing agent, an oxidizing agent, a carbonizing agent, or a nitriding agent.

11. The method of claim 10, wherein the metal precursor comprises a metal and one or more ligands.

12. The method of claim 1, wherein the first silanol comprises a compound represented by the formula: 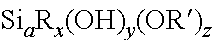
where a is 1, 2, or 3;
where x is 1, 2, or 3;
where y is 1 or 2;
where z is an integer satisfying z=4-x-y for each silicon atom in the compound;
where each R is independently selected from a linear or branched C1-C8 alkyl group; and
where each R′ is independently selected from a linear or branched C1-C8 alkyl group.

13. The method of claim 12, wherein the first silanol comprises one or more of bis(tert-pentoxy)methylsilanol, tert-butyl (tert-butoxy) silanediol, tert-pentyl(tert-pentoxy) silanediol, or tert-pentyl(tert-butoxy) silanediol.

14. The method of claim 1, wherein the second silanol comprises a compound represented by the formula: 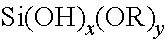
where x is 1 or 2;
where y is 2 or 3; and
where each R is independently selected from a linear or branched C1-C6 alkyl group.

15. The method of claim 14, wherein the second silanol comprises one or more of tris(tert-pentoxy) silanol or tris(tert-butoxy) silanol.

16. A method of selectively depositing a material on a surface of a substrate, the method comprising the steps of:
providing a substrate within a reaction chamber of a reactor, the substrate comprising a first region and a second region;
providing a first silanol to selectively form a blocking layer on the first region, relative to the second region;
selectively depositing a first material on the second region;
providing an activating compound to modify the blocking layer; and
selectively depositing a second material on the first region relative to the second region;
wherein the activating compound enhances growth of the second material on the first region; and
wherein either the activating compound comprises a group 13 element and the second material comprises a group 14 element, or the activating compound comprises a group 14 element and the second material comprises a group 13 element.

17. The method of claim 16, wherein the group 14 element is silicon.

18. The method of claim 17, wherein the activating compound comprises the group 14 element and is a second silanol.

19. The method of claim 16, wherein the group 13 element is aluminum.

20. The method of claim 19, wherein the second material is aluminum oxide.
